(19) United States
(12) Patent Application Publication
(10) Pub. No.: US 2025/0266800 A1
(43) Pub. Date: Aug. 21, 2025

(54) ACOUSTIC RESONATOR PACKAGE

(71) Applicant: Qorvo US, Inc., Greensboro, NC (US)

(72) Inventors: MD Hasnine, Richardson, TX (US); Charles E. Carpenter, Orlando, FL (US); Thomas Scott Morris, Lewisville, NC (US)

(21) Appl. No.: 18/984,207

(22) Filed: Dec. 17, 2024

Related U.S. Application Data
(60) Provisional application No. 63/641,666, filed on May 2, 2024.
(60) Provisional application No. 63/554,350, filed on Feb. 16, 2024.

(51) Int. Cl. H03H 9/02; H03H 3/02; H03H 9/125

(52) U.S. Cl. CPC H03H 9/02157; H03H 3/02; H03H 9/125

(57) ABSTRACT

Acoustic resonator packages are disclosed. A package may be formed with a plurality of devices having respective acoustic resonators. Acoustic devices in a first layer of acoustic devices may be relatively small and have correspondingly small pitches for the input/output (I/O) pins. This first layer of acoustic devices is mounted on a second layer formed from a single acoustic device. The single acoustic device in the second layer acts as a functional interposer for the first layer of acoustic devices. The single acoustic device may have a coarser pitch of I/O pins suitable for attachment to a laminate structure (e.g., a printed circuit board or the like) and provide interconnections between these coarser I/O pins to the fine pitch I/O pins of the devices in the first layer. Further, the single acoustic device may act as a heat spreader and/or heat sink for the acoustic devices in the first layer.

### PRIORITY APPLICATIONS

The present application is related to U.S. Provisional Patent Application Ser. No. 63/554,350 filed on Feb. 16, 2024, and entitled “FUNCTIONAL INTERPOSER FOR RF INTEGRATION,” the contents of which are incorporated herein by reference in its entirety.

The present application is related to U.S. Provisional Patent Application Ser. No. 63/641,666 filed on May 2, 2024, and entitled “ACOUSTIC RESONATOR PACKAGE,” the contents of which are incorporated herein by reference in its entirety.

### BACKGROUND

### I. Field of the Disclosure

The technology of the disclosure relates generally to acoustic device packages and particularly to a package with multiple acoustic devices therein.

### II. Background

Computing devices abound in modem society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase bandwidth available to send and receive data. The increased bandwidth has led to the adoption of acoustic resonators for various elements within the communication device. Concurrently, there has been continued pressure to reduce the size of elements within the communication device. Providing acoustic resonators in increasingly small packages provides room for innovation.

### SUMMARY

Aspects disclosed in the detailed description include acoustic resonator packages. In particular, a package may be formed with a plurality of devices having respective acoustic resonators. Acoustic devices in a first layer of acoustic devices may be relatively small and have correspondingly small pitches for the input/output (I/O) pins. This first layer of acoustic devices is mounted on a second layer formed from a single acoustic device. The single acoustic device in the second layer acts as a functional interposer for the first layer of acoustic devices. That is, the single acoustic device may have a coarser pitch of I/O pins suitable for attachment to a laminate structure (e.g., a printed circuit board or the like) and provide interconnections between these coarser I/O pins to the fine pitch I/O pins of the devices in the first layer. Further, the single acoustic device may act as a heat spreader and/or heat sink for the acoustic devices in the first layer. By stacking the acoustic devices in this arrangement within the package, a suitably small package may be provided for use in a communication device.

In this regard, in one aspect, a package is disclosed. The package includes an interposer layer comprising a first radio frequency (RF) acoustic resonator device, the interposer layer comprising a first side having a plurality of I/O elements thereon at a first pitch, and a second side having a second plurality of I/O elements thereon. The package also includes at least one die positioned on the second side of the interposer layer, the at least one die comprising a plurality of micro-bumps electrically coupled to the second plurality of I/O elements at a second pitch different than the first pitch.

In another aspect, a communication device is disclosed. The communication device includes a transceiver and a filter coupled to the transceiver. The filter including a package comprising an interposer layer comprising a first RF acoustic resonator device, the interposer layer comprising a first side having a plurality of I/O elements thereon at a first pitch, and a second side having a second plurality of I/O elements thereon and at least one die positioned on the second side of the interposer layer, the at least one die comprising a plurality of micro-bumps electrically coupled to the second plurality of I/O elements at a second pitch different than the first pitch.

In another aspect, a method of forming a package is disclosed. The method includes forming an interposer layer comprising an RF acoustic device thereon. The method also includes forming external input/output elements on a first side of the interposer layer and attaching at least one die to a second side of the interposer layer, the at least one die comprising a second RF acoustic device.

### BRIEF DESCRIPTION OF THE DRAWINGS

FIG. 1 is a side cross-sectional view of a first package containing acoustic resonators according to an aspect of the present disclosure;

FIG. 2 is a side cross-sectional view of a second package containing acoustic resonators according to an aspect of the present disclosure but having additional thermal vias to assist in heat dissipation;

FIG. 3 is a side cross-sectional view of a third package containing acoustic resonators according to an aspect of the present disclosure but omitting a redistribution layer;

FIG. 4 is a flowchart illustrating a first process for forming the package of FIG. 1;

FIGS. 5A-5M illustrate intermediate assemblies formed while performing the process of FIG. 4;

FIG. 6 is a flowchart of a process for forming the package of FIG. 2;

FIGS. 7A-7L illustrate intermediate assembles formed while performing the process of FIG. 6;

FIG. 8 is a flowchart of a process for forming the package of FIG. 3;

FIGS. 9A-9K illustrate intermediate assemblies formed while performing the process of FIG. 8; and

FIG. 10 is a block diagram of a communication device, which, according to the present disclosure, may include the acoustic resonator packages of FIGS. 1-3.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

As used herein, “pitch” is defined as the distance measured from the center of one element to the center of the next element. Specifically contemplated elements are input/output (I/O) elements, including solder bumps, contact pads, pins, or the like.

Aspects disclosed in the detailed description include acoustic resonator packages. In particular, a package may be formed with a plurality of devices having respective acoustic resonators. Acoustic devices in a first layer of acoustic devices may be relatively small and have correspondingly small pitches for the input/output (I/O) pins. This first layer of acoustic devices is mounted on a second layer formed from a single acoustic device. The single acoustic device in the second layer acts as a functional interposer for the first layer of acoustic devices. That is, the single acoustic device may have a coarser pitch of I/O pins suitable for attachment to a laminate structure (e.g., a printed circuit board or the like) and provide interconnections between these coarser I/O pins to the fine pitch I/O pins of the devices in the first layer. Further, the single acoustic device may act as a heat spreader and/or heat sink for the acoustic devices in the first layer. By stacking the acoustic devices in this arrangement within the package, a suitably small package may be provided for use in a communication device.

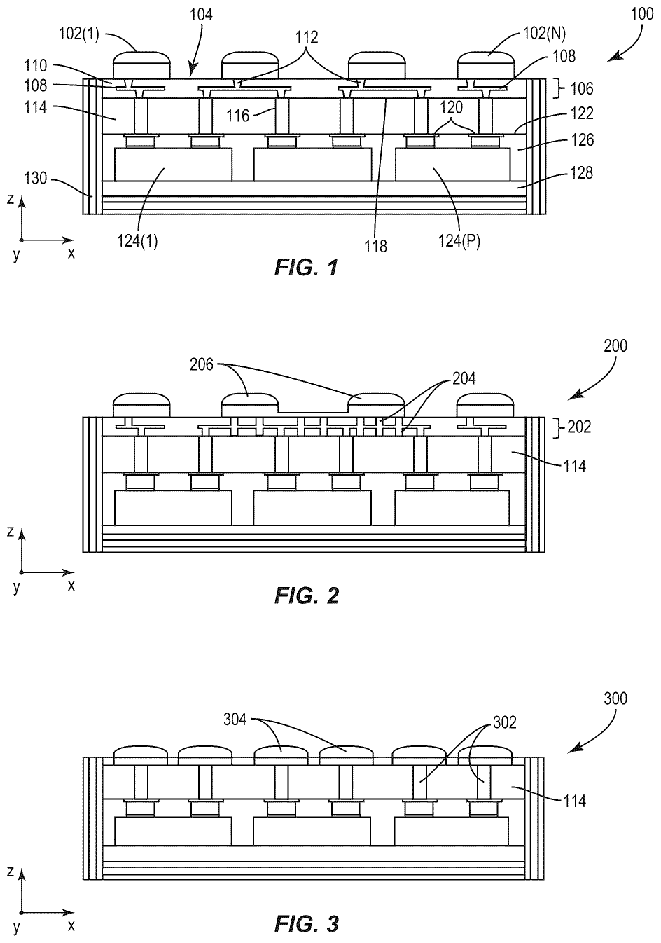

In this regard, FIG. 1 illustrates a package 100, according to exemplary aspects of the present disclosure. The package 100 includes a first set of I/O elements 102(1)-102(N) that are spaced at a first pitch configured to be coupled to a laminate such as a printed circuit board, motherboard, or the like. As illustrated, the I/O elements 102(1)-102(N) are solder balls or the like. The I/O elements 102(1)-102(N) are positioned on a surface 104 of a metallization layer or redistribution layer (RDL) 106. The RDL 106 has internal metal layers 108 sandwiched between dielectric layers 110 with vias 112 interconnecting them.

A first acoustic device 114 is positioned on a second side (opposite the surface 104 in the z-axis direction). The first acoustic device 114 may be a bulk acoustic wave (BAW) device that is instantiated in silicon and has piezoelectric material internal layers (e.g., aluminum nitride (AlN) or scandium doped AlN). It should be appreciated that the acoustic device is likely an acoustic resonator and more likely a plurality of acoustic resonators formed into a filter, as is well understood. In addition to the normal acoustic device structures, the first acoustic device 114 may include first internal I/O contacts 116 on a first side 118, where the I/O contacts 116 have a second pitch. The second pitch may be the same as or different than the first pitch.

The first acoustic device 114 further has second internal I/O contacts 120 on a second side 122 opposite the first side 118 (in the z-axis direction). The second internal I/O contacts 120 have a third pitch and are configured to couple to one or more acoustic devices 124(1)-124(P). The acoustic devices 124(1)-124(P) are substantially smaller than the first acoustic device 114 (e.g., approximately 250 micrometers×250 micrometers (and sometimes less) in the x-y directions). Other than size, the acoustic devices 124(1)-124(P) may also have I/O contact pitches which are too fine for direct attachment to an underlying substrate. Accordingly, the third pitch is substantially finer than the second pitch or first pitch to allow connection to the acoustic devices 124(1)-124(P). In this regard, the first acoustic device 114 acts as a functional interposer for the acoustic devices 124(1)-124(P), acting to provide a transformation function for the third pitch to the first pitch. The second pitch is likely somewhere between the first pitch and the second pitch but can be equal to either without departing from the present disclosure. Note further that the third pitch can be non-uniform. For example, the pitch of the acoustic device 124(1) may be different than the pitch of the acoustic device 124(P).

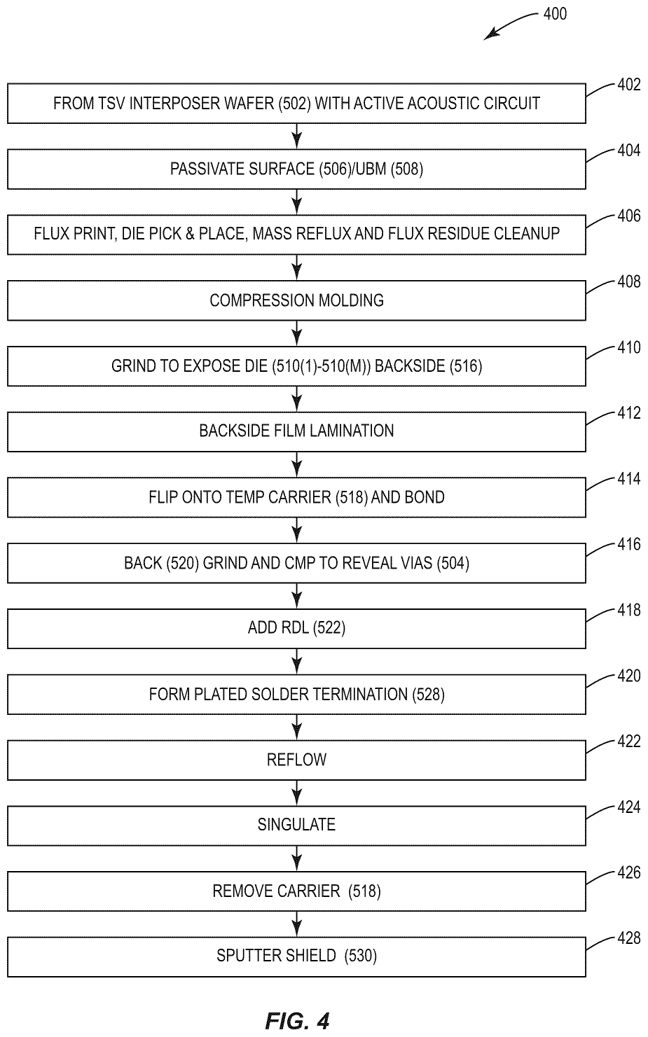

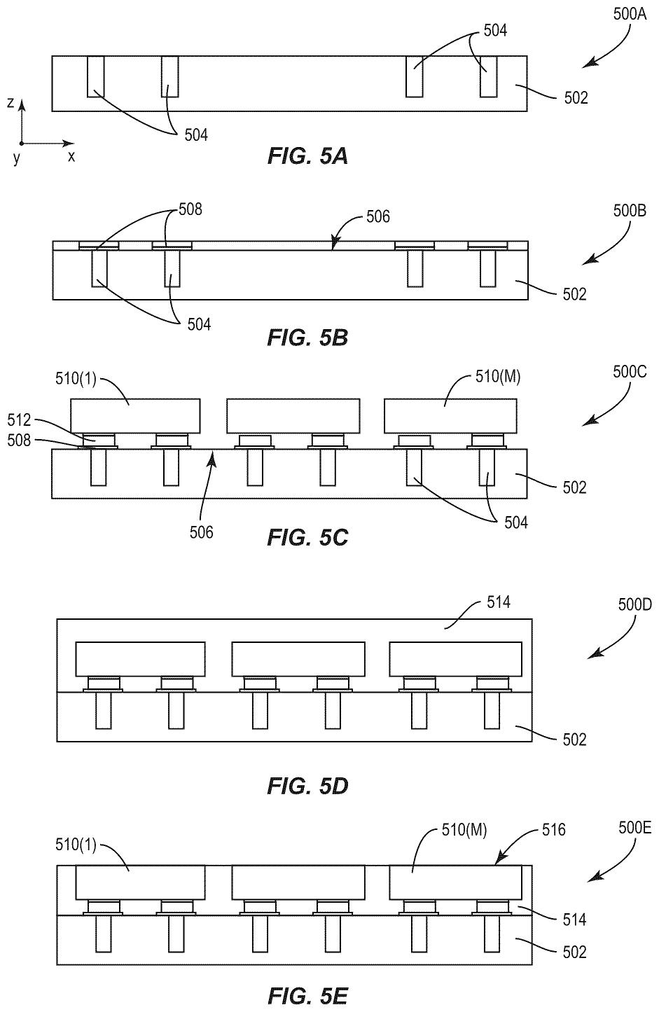

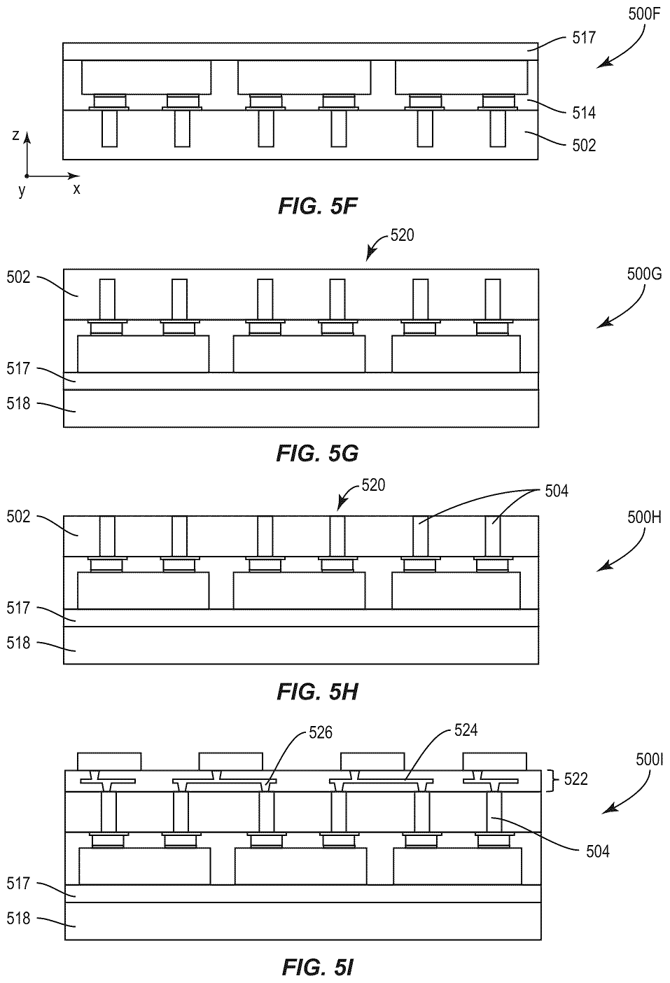

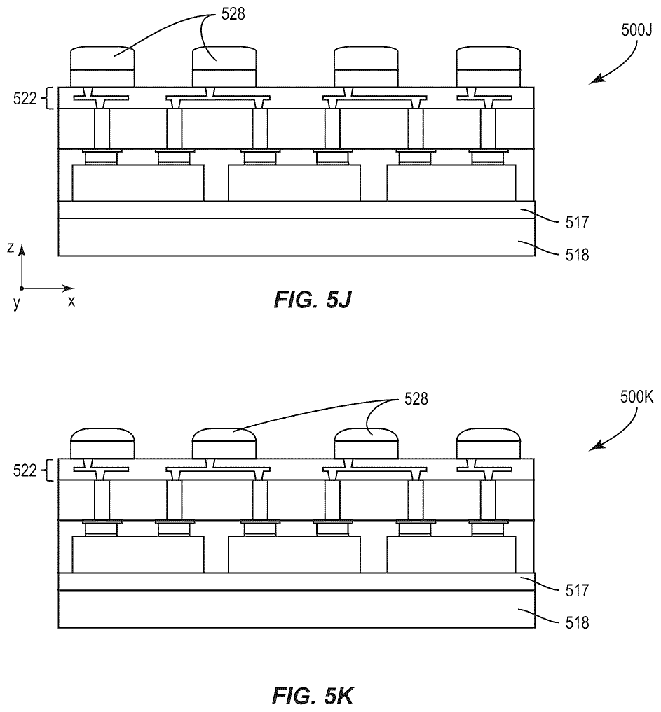

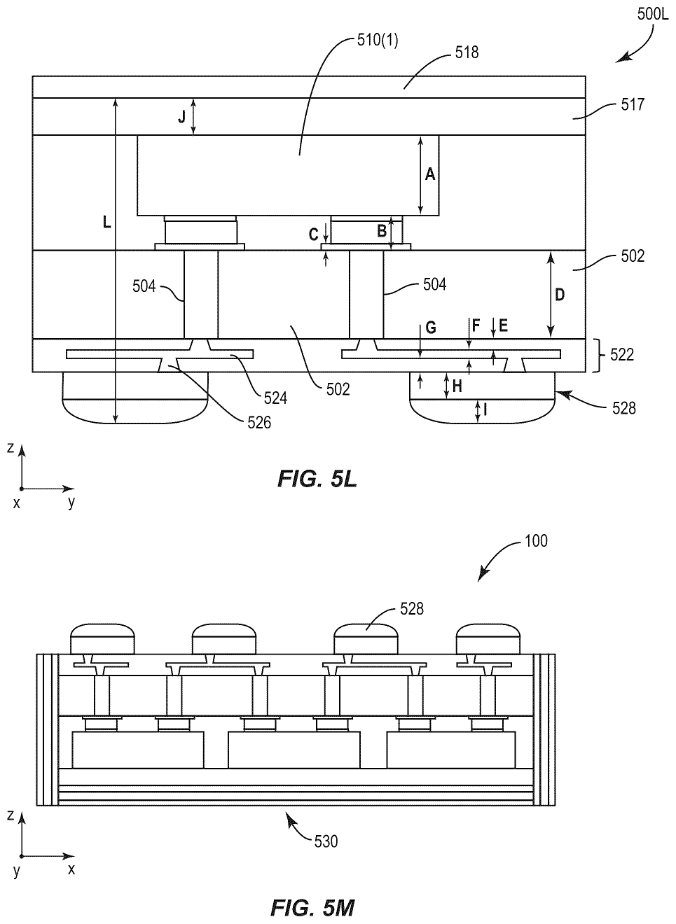

With continued reference to FIG. 1, a mold material 126 may surround and encapsulate the acoustic devices 124(1)-124(P). A backside film 128 may cover the mold material 126, and a shield 130 may cover a portion of the package 100. Details on formation of the package 100 are provided below with reference to FIGS. 4-5M.

In addition to acting as a pitch transformation function for the I/O elements of the various acoustic devices, the first acoustic device 114 also helps remove heat from the acoustic devices 124(1)-124(P). That is, if the challenges of mounting the acoustic devices 124(1)-124(P) directly on the substrate were overcome (a non-trivial challenge given the pitches in question), the small size of the acoustic devices 124(1)-124(P) and the general thermal resistance of most substrates means that heat generated in the acoustic devices 124(1)-124(P) would be trapped within the acoustic devices 124(1)-124(P). Such heat entrapment is generally undesirable. In contrast, by placing the acoustic devices 124(1)-124(P) on the relatively low thermal resistance silicon of the first acoustic device 114, the heat may be pulled from the acoustic devices 124(1)-124(P), and the heat spread in such a way that the risk of damage to the acoustic devices is reduced and that temperature-induced performance variations are also reduced.

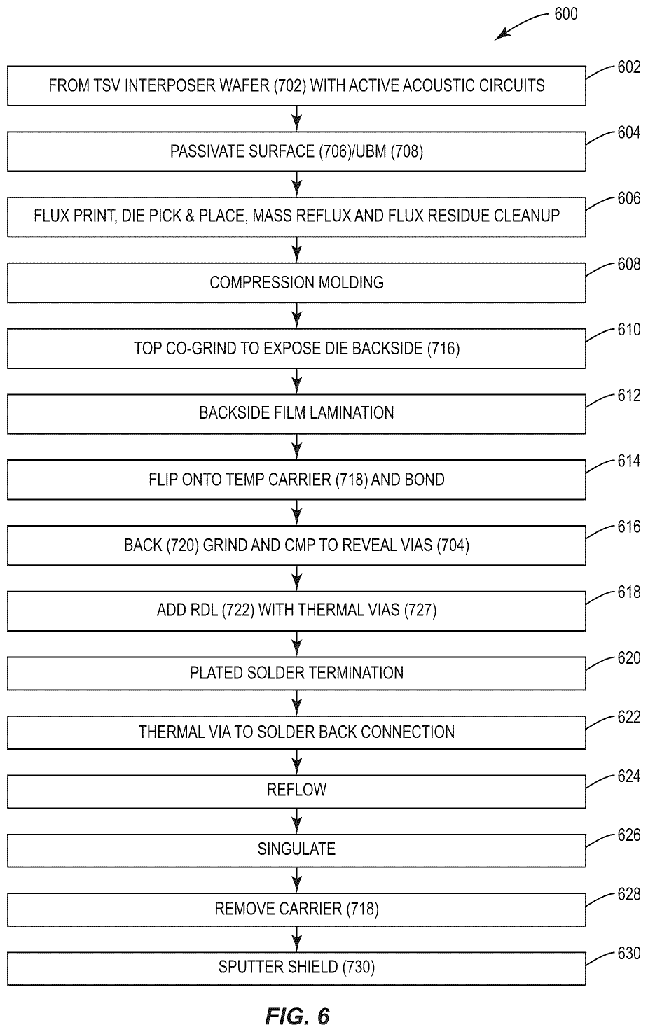

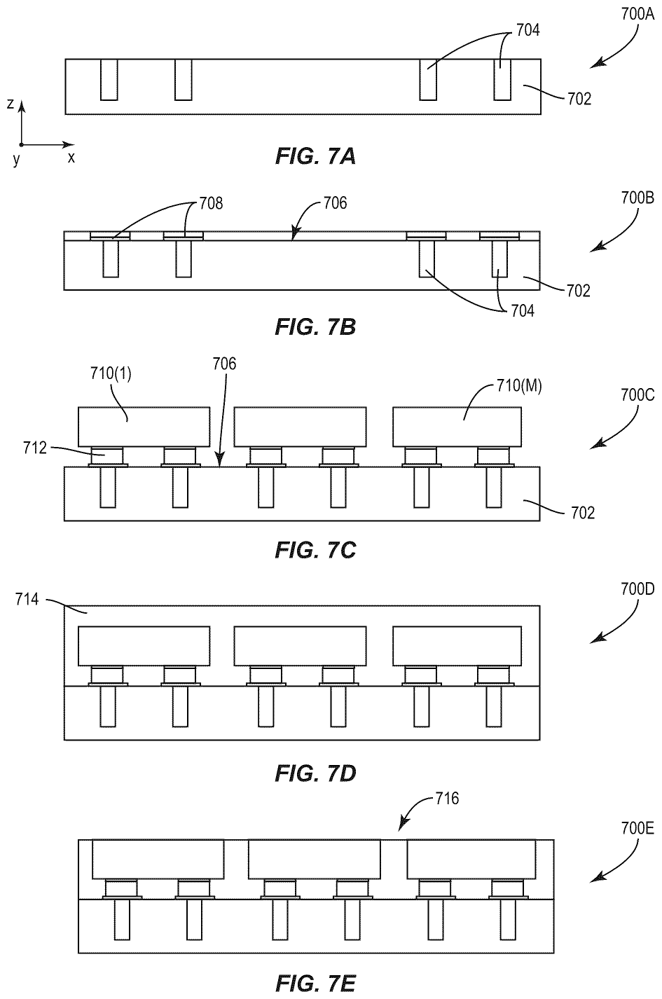

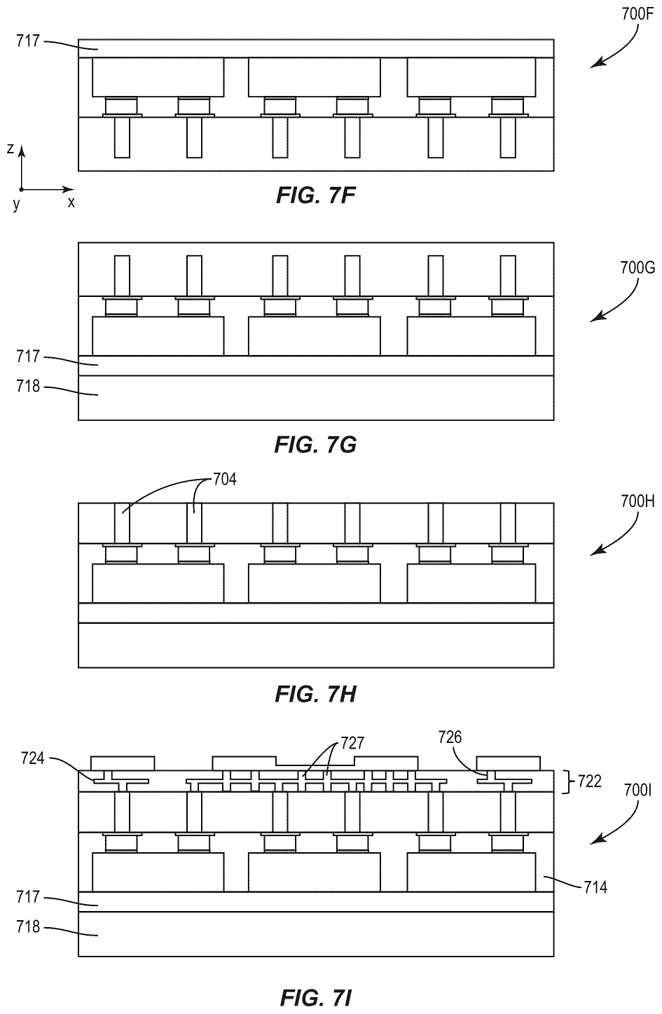

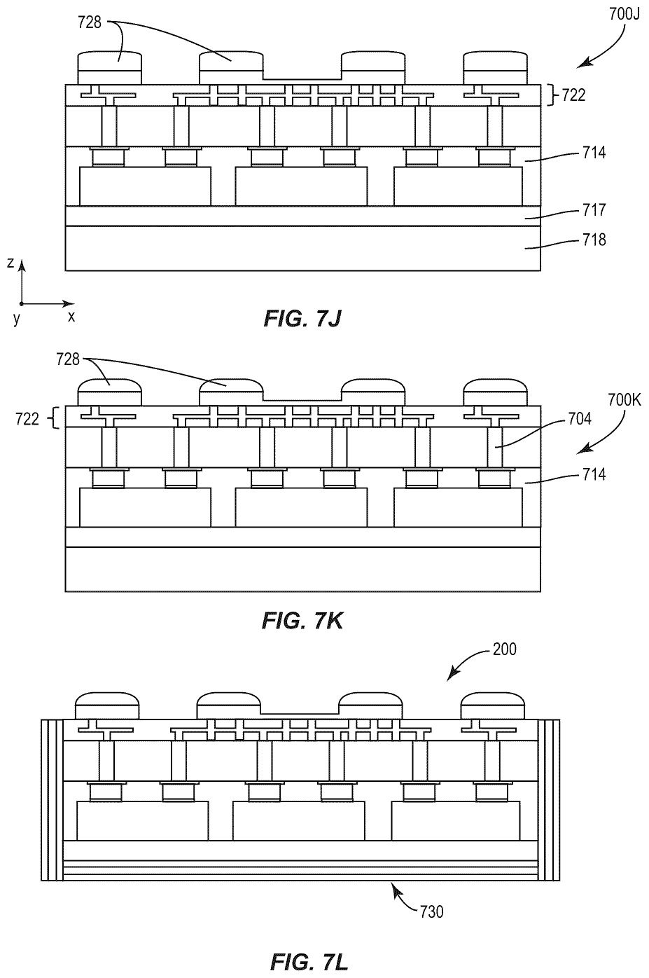

FIG. 2 illustrates a package 200 that is similar in many regards to the package 100, but the RDL 106 is replaced with an RDL 202 that includes thermal conduits or vias 204 that assist in pulling heat out of the first acoustic device 114 and spreading that heat between ground solder balls 206 to assist in moving heat. Other elements remain the same, and a repeated discussion is omitted. Additional details about the formation of the package 200 are provided below with reference to FIGS. 6-7L.

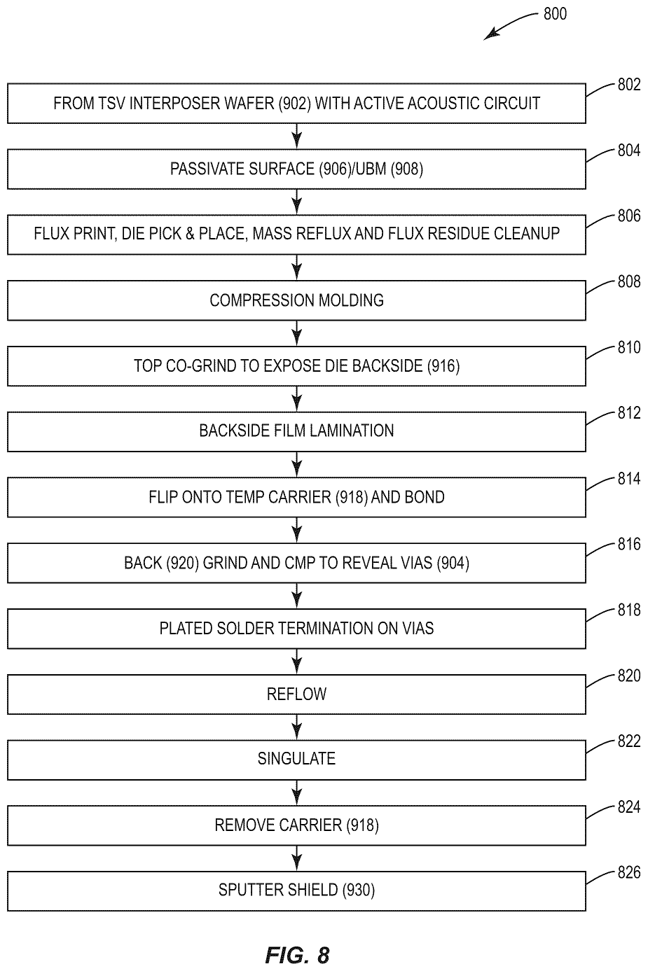

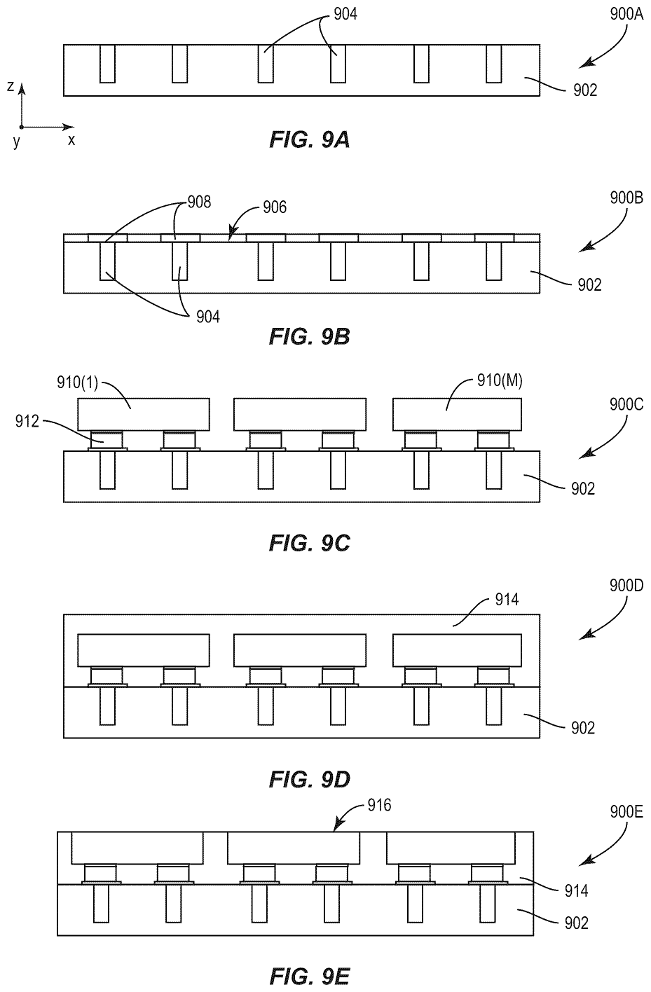

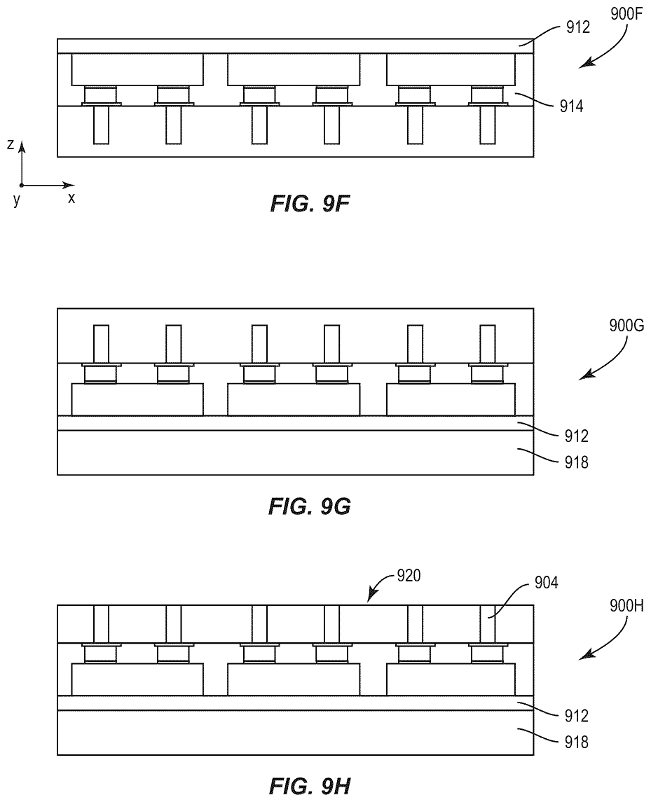

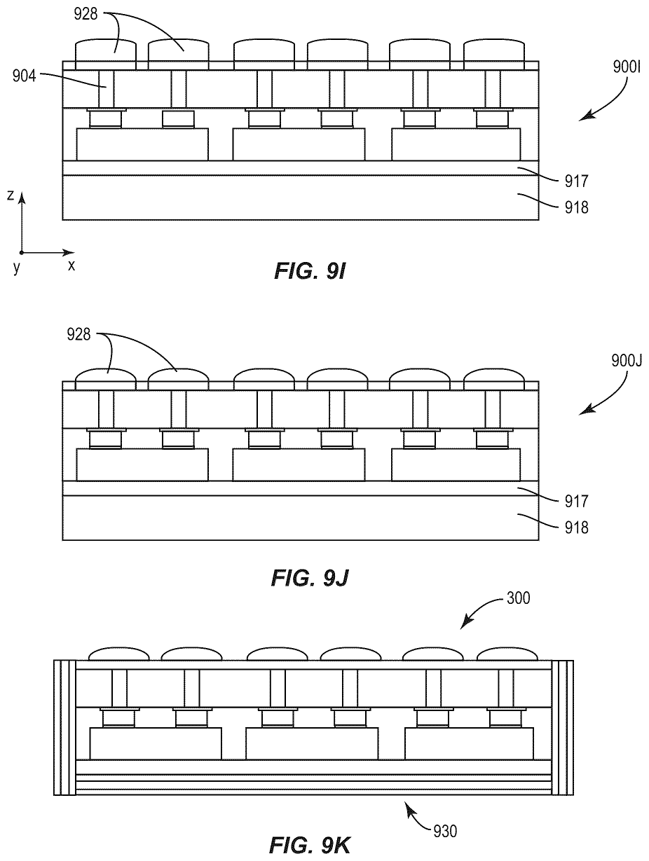

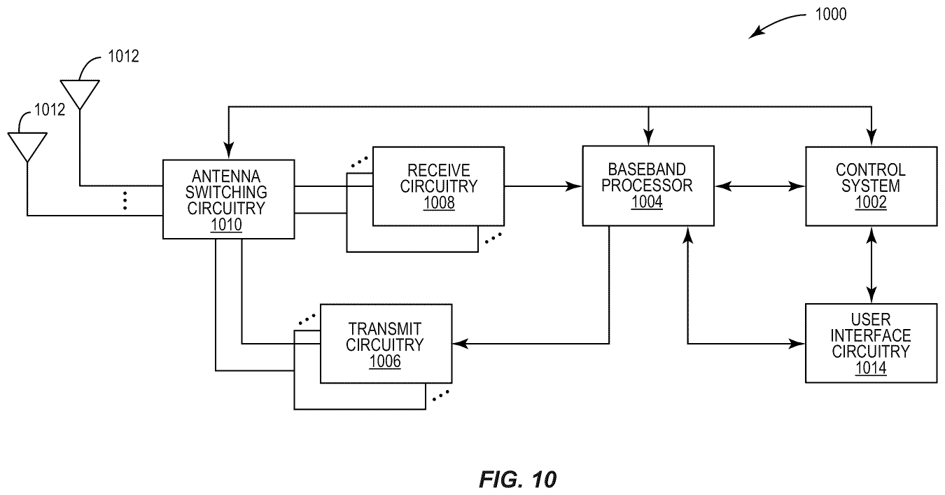

FIG. 3 illustrates a package 300 that omits the RDL 106/202 entirely, relying on vias 302 in the first acoustic device 114 to couple to solder balls 304 as needed or desired. Additional details about the formation of the package 300 are provided below with reference to FIGS. 8-9K.

While it is specifically contemplated that the packages 100, 200, and 300 may be radio frequency (RF) filters, the present disclosure is not so limited. The packages 100, 200, and 300 may also be used for switches, integrated passive devices (IPDs), low noise amplifiers (LNAs), and the like. In essence, multiple RF chips may be integrated into a submodule, reducing the overall module's×Y dimensions without degrading the thickness (z-axis).

Additional details regarding the package 100 and the formation thereof are provided with reference to FIGS. 4-5M. In particular, FIG. 4 sets forth a process 400 for forming the package 100, and FIGS. 5A-5L illustrate intermediate products 500A-500L produced by the steps of the process 400 culminating in the package 100 in FIG. 5M.

In this regard, the process 400 begins by forming a through silicon via (TSV) interposer wafer 502 with an active acoustic circuit (block 402, FIG. 5A) to form beginning product 500A. That is, the TSVs 504 are formed in the wafer 502 before acoustic circuit fabrication and are, for example, copper-filled blind TSVs. The TSVs 504 are spaced such that they may accommodate an ultra-fine pitch for micro-bumps in the RF dies, as further explained below.

The process 400 continues with passivation of the surface 506 and under bump metal (UBM) 508 formation (block 404, FIG. 5B) to form intermediate product 500B. Note that the passivation may involve re-passivation to protect the surface 506 more fully. Note that the UBM 508 are formed such that they are electrically coupled to the TSVs 504. In an exemplary aspect, the UBM are nickel-gold (Ni—Au) layers.

The process 400 continues with a flux print, die pick and place, mass reflux, and flux residue cleanup (block 406, FIG. 5C) to form intermediate product 500C. That is, (potentially differently sized) dies 510(1)-510(M), which may have micro-bumps 512, are placed on the surface 506 and electrically coupled to the TSVs 504 through the UBM 508. By differently sized, it means that not only are dies 510(1)-510(M) smaller than the wafer 502, but they also may be differently sized from one another, although, as currently contemplated all are less than 250 micrometers by 250 micrometers.

The process 400 continues with liquid compression molding (block 408, FIG. 5D) to form intermediate product 500D with mold 514. The mold is cured and then ground to expose the die 510(1)-510(M) backside 516 (block 410, FIG. 5E) to form intermediate product 500E. This grinding reduces the thickness of the dies 510(1)-510(M) to approximately 50 micrometers, significantly reducing overall package thickness. This grinding also presents an alternative to thinning the dies, which is typically performed at the wafer fabrication.

A backside film lamination is then performed (block 412, FIG. 5F) to form a dielectric layer 517 (also sometimes referred to as a film) in intermediate product 500F. The intermediate product 500F is then flipped onto a temporary carrier 518 and bonded (block 414, FIG. 5G) to form intermediate product 500G. That is, the temporary carrier 518 is bonded to the dielectric layer 517.

The now top side or back 520 of the wafer 502 is ground and chemically mechanically polished (CMP) to reveal the TSVs 504 (block 416, FIG. 5H) to form intermediate product 500H. This grinding may reduce the thickness (z-axis) of the wafer 502 by approximately 50 micrometers. This thickness may result in an overall package 100 thickness of less than approximately 230 micrometers.

The process 400 continues by adding an RDL 522 (block 418, FIG. 5I) to form intermediate product 500I. As described above, the RDL 522 may include internal metal layers 524 and internal vias 526 that allow interconnections with the TSVs 504.

The process 400 continues with forming plated solder terminations (block 420, FIG. 5J) to form intermediate product 500J with plated solder bumps 528. The plated solder bumps 528 are reflowed (block 422, FIG. 5K) to form intermediate product 500K and singulated (block 424). The temporary carrier 518 is removed (block 426, FIG. 5L) to form intermediate product 500L. Note that 500L includes various dimensions. Exemplary values for these dimensions are provided in Table 1 below.

TABLE 1

| | | | Target |
|---|---|---|---|
| Symbol | Layer | Material | thickness, um |
| A | BAW 2 | Si | 40-50 |
| B | Solder | Sn | 30 |
| C | UBM | Ni 2 um/Au 0.5 um | ~3 |
| D | BAW 1 | Si Interposer | 50 |
| E | PI 1 | BL- 301 | 5 |
| F | RDL1(L/S) | Cu | 5/5 |
| G | PI 2 | BL- 301 | 5 |
| H | FS pad | Ti/Cu seed/Cu pad | 7 |
| | | 5 um/Ni 2 um | |
| I | Micro-bump | Sn1.8Ag | 35 |
| J | Backside film | BSC | 25 |
| L | Total thickness | | 215 |

Finally, a shield 530 is sputtered on the package to form package 100 (block 428, FIG. 5M).

The package 100 is now ready to be fixed to a laminate-based substrate (not shown).

A process 600 for creating the package 200 is substantially similar in many steps, but the process 600 is set forth in full in FIG. 6 along with FIGS. 7A-7K showing intermediate products 700A-700K with finished package 200 presented again in FIG. 7L.

In this regard, the process 600 begins by forming a through silicon via (TSV) interposer wafer 702 with active acoustic circuits (block 602, FIG. 7A) to form beginning product 700A. That is, the TSVs 704 are formed in the wafer 702 before acoustic circuit fabrication and are, for example, copper-filled blind TSVs. The TSVs 704 are spaced such that they may accommodate an ultra-fine pitch for micro-bumps in the RF dies, as further explained below.

The process 600 continues with passivation of the surface 706 and under bump metal (UBM) 708 formation (block 604, FIG. 7B) to form intermediate product 700B. Note that the passivation may involve re-passivation to protect the surface 706 more fully. Note that the UBM 708 are formed such that they are electrically coupled to the TSVs 704. In an exemplary aspect, the UBM are nickel-gold (Ni—Au) layers.

The process 600 continues with a flux print, die pick and place, mass reflux, and flux residue cleanup (block 606, FIG. 7C) to form intermediate product 700C. That is, (potentially differently sized) dies 710(1)-710(M), which may have micro-bumps 712, are placed on the surface 706 and electrically coupled to the TSVs 704 through the UBM 708. By differently sized, it means that not only are dies 710(1)-710(M) smaller than the wafer 702, but they also may be differently sized from one another, although, as currently contemplated, all are less than 250 micrometers by 250 micrometers.

The process 600 continues with liquid compression molding (block 608, FIG. 7D) to form intermediate product 700D with mold 714. The mold is cured and then ground to expose the die 710(1)-710(M) backside 716 (block 610, FIG. 7E) to form intermediate product 700E. This grinding reduces the thickness of the dies 710(1)-710(M) to approximately 50 micrometers, significantly reducing overall package thickness. This grinding also presents an alternative to thinning the dies, which is typically performed at the wafer fabrication.

A backside film lamination is then performed (block 612, FIG. 7F) to form a dielectric layer 717 in intermediate product 700F. The intermediate product 700F is then flipped onto a temporary carrier 718 and bonded (block 614, FIG. 7G) to form intermediate product 700G. That is, the temporary carrier 718 is bonded to the dielectric layer 717.

The now top side or back 720 of the wafer 702 is ground and chemically mechanically polished (CMP) to reveal the TSVs 704 (block 616, FIG. 7H) to form intermediate product 700H. This grinding may reduce the thickness (z-axis) of the wafer 702 by approximately 50 micrometers. This thickness may result in an overall package 100 thickness of less than approximately 230 micrometers.

The process 600 continues by adding an RDL 722 (block 618, FIG. 7I) to form intermediate product 700I. As described above, the RDL 722 may include internal metal layers 724 and internal vias 726 that allow interconnections with the TSVs 704. Additionally, the RDL 722 may include thermal vias 727.

The process 600 continues with forming plated solder terminations (block 620, FIG. 7J) to form intermediate product 700J with plated solder bumps 728. The plated solder bumps 728 are reflowed (block 622, FIG. 7K) to form intermediate product 700K and singulated (block 624). The temporary carrier 718 is removed (block 626), and a shield 730 is applied to form package 200 (block 628, FIG. 7L).

A process 800 for making the package 300 is substantially similar in many steps, but the process 800 is set forth in full in FIG. 8 along with FIGS. 9A-9K showing intermediate products 900A-900J with finished package 300 presented again in FIG. 9K.

In this regard, the process 800 begins by forming a through silicon via (TSV) interposer wafer 902 with active acoustic circuits (block 802, FIG. 9A) to form beginning product 900A. That is, the TSVs 904 are formed in the wafer 902 before acoustic circuit fabrication and are, for example, copper-filled blind TSVs. The TSVs 904 are spaced such that they may accommodate an ultra-fine pitch for micro-bumps in the RF dies, as further explained below.

The process 800 continues with passivation of the surface 906 and under bump metal (UBM) 908 formation (block 804, FIG. 9B) to form intermediate product 900B. Note that the passivation may involve re-passivation to protect the surface 906 more fully. Note that the UBM 908 are formed such that they are electrically coupled to the TSVs 904. In an exemplary aspect, the UBM are nickel-gold (Ni—Au) layers.

The process 800 continues with a flux print, die pick and place, mass reflux, and flux residue cleanup (block 806, FIG. 9C) to form intermediate product 900C. That is, (potentially differently sized) dies 910(1)-910(M), which may have micro-bumps 912, are placed on the surface 906 and electrically coupled to the TSVs 904 through the UBM 908. By differently sized, it means that not only are dies 910(1)-910(M) smaller than the wafer 902, but they also may be differently sized from one another, although, as currently contemplated, all are less than 250 micrometers by 250 micrometers.

The process 800 continues with liquid compression molding (block 808, FIG. 9D) to form intermediate product 900D with mold 914. The mold is cured and then ground to expose the die 910(1)-910(M) backside 916 (block 810, FIG. 9E) to form intermediate product 900E. This grinding reduces the thickness of the dies 910(1)-910(M) to approximately 50 micrometers, significantly reducing overall package thickness. This grinding also presents an alternative to thinning the dies, which is typically performed at the wafer fabrication.

A backside film lamination is then performed (block 812, FIG. 9F) to form a dielectric layer 917 in intermediate product 900F. The intermediate product 900F is then flipped onto a temporary carrier 918 and bonded (block 814, FIG. 9G) to form intermediate product 900G. That is, the temporary carrier 918 is bonded to the dielectric layer 917.

The now top side or back 920 of the wafer 902 is ground and chemically mechanically polished (CMP) to reveal the TSVs 904 (block 816, FIG. 9H) to form intermediate product 900H. This grinding may reduce the thickness (z-axis) of the wafer 902 by approximately 50 micrometers. This thickness may result in an overall package 100 thickness of less than approximately 230 micrometers.

The process 800 continues with forming plated solder terminations (block 818, FIG. 9I) to form intermediate product 900I with plated solder bumps 928. The plated solder bumps 928 are reflowed (block 820, FIG. 9J) to form intermediate product 900J and singulated (block 822). The temporary carrier 918 is removed (block 824), and a shield 930 is applied to form package 300 (block 826, FIG. 9K).

The acoustic resonator package, according to aspects disclosed herein, may be provided in or integrated into any processor-based device that relies on acoustic resonators (e.g., in a communication circuit). Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

FIG. 10 is a schematic diagram of an exemplary communication device 1000 wherein the acoustic resonator package can be provided. Herein, the communication device 1000 can be any type of communication device, wired or wireless, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1012 through the antenna switching circuitry 1010. While not shown, a filter may be positioned between the power amplifier and the antennas 1012, and such filter may be formed from one or more acoustic resonators assembled into, for example, the acoustic resonator package of the present disclosure. The multiple antennas 1012 and the replicated transmit and receive circuitries 1006, 1008 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
an interposer layer comprising a first radio frequency (RF) acoustic resonator device, the interposer layer comprising a first side having a plurality of input/output (I/O) elements thereon at a first pitch, and a second side having a second plurality of I/O elements thereon; and
at least one die positioned on the second side of the interposer layer, the at least one die comprising a plurality of micro-bumps electrically coupled to the second plurality of I/O elements at a second pitch different than the first pitch. (forming external input/output elements on a first side of the interposer layer; and attaching at least one die to a second side of the interposer layer, the at least one die comprising a second RF acoustic device).

2. The package of claim 1, further comprising a redistribution layer coupled to the first side of the interposer layer.

3. The package of claim 2, wherein the redistribution layer comprises a plurality of metal layers and a plurality of vias.

4. The package of claim 2, wherein the redistribution layer comprises a plurality of thermal vias.

5. The package of claim 2, wherein the redistribution layer comprises a plurality of external I/O elements configured to be coupled to a laminate substrate, the plurality of external I/O elements having a third pitch coarser than the second pitch.

6. The package of claim 1, wherein the at least one die comprises a second RF acoustic resonator.

7. The package of claim 1, further comprising a plurality of external I/O elements electrically coupled to respective ones of the plurality of I/O elements.

8. The package of claim 1, wherein the interposer layer comprises a silicon material configured to spread heat from the at least one die.

9. The package of claim 1, further comprising a mold material surrounding and encapsulating the at least one die.

10. The package of claim 9, further comprising a shield surrounding the mold material.

11. The package of claim 1, wherein the interposer layer comprises a through silicon via (TSV) coupling at least one of the plurality of input/output (I/O) elements to at least one of the second plurality of I/O elements thereon.

12. The package of claim 1, further comprising a dielectric layer positioned on the at least one die.

13. A communication device comprising:
a transceiver;
a filter coupled to the transceiver, the filter comprising a package comprising:
an interposer layer comprising a first radio frequency (RF) acoustic resonator device, the interposer layer comprising a first side having a plurality of input/output (I/O) elements thereon at a first pitch, and a second side having a second plurality of I/O elements thereon; and
at least one die positioned on the second side of the interposer layer, the at least one die comprising a plurality of micro-bumps electrically coupled to the second plurality of I/O elements at a second pitch different than the first pitch.

14. A method of forming a package, comprising:
forming an interposer layer comprising a radio frequency (RF) acoustic device therein;
forming external input/output elements on a first side of the interposer layer; and
attaching at least one die to a second side of the interposer layer, the at least one die comprising a second RF acoustic device.

15. The method of claim 14, further comprising adding a redistribution layer to the first side of the interposer layer.

16. The method of claim 15, wherein adding the redistribution layer comprises adding a redistribution layer with internal metal layers and vias.

17. The method of claim 15, further comprising forming solder bumps on the redistribution layer.

18. The method of claim 14, further comprising encapsulating the at least one die with a mold material.

19. The method of claim 18, further comprising grinding the mold material to expose a backside of the at least one die.

20. The method of claim 14, further comprising positioning a shield around the at least one die.
